(19) United States
(12) Patent Application Publication
(10) Pub. No.: US 2005/0014372 A1
(43) Pub. Date: Jan. 20, 2005

(54) Etching method and plasma etching processing apparatus

(76) Inventors: Satoshi Shimonishi, Oita-shi (JP); Takanori Matsumoto, Mie (JP); Katsumi Horiguchi, Nirasaki-shi (JP); Kenji Yamamoto, Yamanashi (JP); Fumihiko Higuchi, Yamanashi (JP)

Correspondence Address: Finnegan, Henderson, Farabow,;Garrett & Dunner, L.L.P., 1300 I Street, N.W., Washington, DC, 20005-3315, US

(21) Appl. No.: 10/875,961

(22) Filed: Jun. 25, 2004

Related U.S. Application Data
(63) Continuation of application No. PCT/JP02/13479, filed on Dec. 25, 2002.

(30) Foreign Application Priority Data
Dec. 27, 2001 (JP) JP2001-397899

(51) Int. Cl. H01L 21/302; H01L 21/461

(52) U.S. Cl. 438/689

(57) ABSTRACT

When etching a silicon layer 210 with a processing gas containing a mixed gas constituted of HBr gas, and O₂ gas and SiF₄ gas and further mixed with both of or either of SF₆ gas and NF₃ gas by using a pre-patterned mask having a silicon oxide film layer 204 inside an airtight processing container 102, high-frequency power with a first frequency is applied from a first high-frequency source 118 and high-frequency power with a second frequency lower than the first frequency is applied from a second high-frequency source 138 to a lower electrode 104 on which a workpiece is placed. Through this etching process, holes or grooves achieving a high aspect ratio are formed in a desirable shape at the silicon layer.

### CROSS-REFERENCE TO RELATED APPLICATIONS

This is a continuation of Application of International Application PCT/JP02/13479, filed Dec. 25, 2002, which was not published under PCT Article 21(2) in English.

### TECHNICAL FIELD

The present invention relates to an etching method and a plasma etching processing apparatus.

### BACKGROUND OF THE INVENTION

To keep pace with increasingly higher density and higher integration achieved in semiconductor elements, the need to form holes with higher aspect ratios has arisen in recent years. Ideally, such a hole will be formed so that its sidewall ranges substantially perpendicular to the hole opening plane while achieving a smooth contour.

Holes with a desirably high aspect ratio may be formed at a silicon layer through an etching process executed by setting the temperature of a lower electrode on which a workpiece is placed to a level equal to or lower than, for instance, 60° C. within an airtight processing container, using a processing gas constituted of a mixed gas containing HBr gas, NF₃ gas and O₂ gas or a mixed gas containing HBr gas, SF₆ gas and O₂ gas and setting the pressure inside the processing container to 150 mTorr or lower.

Alternatively, such holes may be formed through an etching process executed by using a processing gas constituted of a mixed gas containing HBr gas, SiF₄ gas, SF₆ gas and O₂ gas mixed with He gas and supplied to an airtight processing container, setting the pressure inside the processing container to 50 to 150 mTorr and applying a magnetic field of 100 gauss or lower which is perpendicular to the electric field, as disclosed in Japanese Patent Laid Open Publication No. 6-163478.

However, a satisfactory etching selection ratio, which is a ratio of the etching rate of silicon, i.e., the target material being etched, to the etching rate of a silicon oxide film used as a mask during the etching process (hereafter simply referred to as an etching selection ratio) is not achieved with the first method described above, and for this reason, it is difficult to form deep holes in the silicon while ensuring that the mask remains unetched over the required thickness.

Japanese Patent Laid Open Publication No. 6-163478 discloses a method for forming grooves (trenches) having a width of 1 to 120 μm. However, it does not disclose a method for forming holes (or grooves) having a very small hole diameter (or a groove with) of 1 μm or smaller (e.g., approximately 0.2 μm).

An object of the present invention, which has been completed by addressing the problems of the etching methods and the plasma etching processing apparatuses in the related art discussed above, is to provide a new and improved etching method and a new and improved plasma etching processing apparatus, that make it possible to form small holes (grooves) achieving a high aspect ratio and a desirable shape at a silicon layer.

### SUMMARY OF THE INVENTION

In order to achieve the object described above, an aspect of the present invention provides an etching method for etching a silicon layer of a workpiece with a processing gas containing a mixed gas constituted of HBr gas, O₂ gas and SiF₄ gas and further mixed with both of or either of SF₆ gas and NF₃ gas by using a pre-patterned mask within an airtight processing container, characterized in that a first high-frequency power with a first frequency and second high-frequency power with a second frequency lower than the first frequency are applied to a lower electrode on which the workpiece is placed.

It is desirable that the first frequency be 27.12 MHz or higher and that the second frequency be 3.2 MHz. In the airtight processing container, a horizontal magnetic field perpendicular to the electric field, e.g., a horizontal magnetic field achieving an intensity level of 170 gauss or higher over a central area of the workpiece, may be formed.

In addition, the temperature of the lower electrode may be set equal to or higher than 70° C. and equal to or lower than 250° C. and the pressure inside the processing container may be set equal to or higher than 150 mTorr and equal to or lower than 500 mTorr. The flow rates of the gases constituting the processing gas may be set to 100 to 600 sccm for the HBr gas, to 2 to 60 sccm for the O₂ gas and 2 to 50 sccm for the SiF₄ gas. If SF₆ gas is contained in the processing gas, its flow rate may be set to 1 to 60 sccm, whereas if NF₃ gas is contained in the processing gas, its flow rate may be set to 2 to 80 sccm.

An aspect ratio of 30 or higher can be achieved for holes or grooves formed through etching. It is desirable that the pre-patterned mask include at least a silicon oxide film layer. The etching ratio (etching selection ratio) of the silicon layer, i.e., the etching target material with respect to the extent to which the mask is etched at its shoulders may be 6 or higher. By adopting this method, holes or grooves achieving a high aspect ratio with a small hole diameter or groove width of 1 μm or less can be formed in a desired shape at the silicon layer.

In order to achieve the object described above, another aspect of the present invention provides an etching method for etching a silicon layer of a workpiece with a processing gas containing a mixed gas constituted of HBr gas, O₂ gas and SiF₄ gas and further mixed with both of or either of SF₆ gas and NF₃ gas by using a pre-patterned mask within an airtight processing container and applying first high frequency power with a first frequency and second high frequency power with a second frequency lower than the first frequency to a lower electrode on which the workpiece is placed, comprising a first step in which an upper portion of the silicon layer is etched in a funnel shape and a second step executed following the first step, in which the remaining silicon layer is etched to form a smooth surface, the section of which ranges substantially perpendicular to the surface of the workpiece.

The second step may be executed by increasing the second high-frequency power compared to the first step. In addition, the second step may include a plurality of steps. When executing the individual steps constituting the second step, the level of the second high-frequency power and the flow rate of the O₂ gas may be varied. It is particularly desirable to set a higher flow rate for the O₂ gas in later steps among the plurality of steps constituting the second step. Through this method, the shape of the holes or grooves being formed can be controlled more accurately.

In order to achieve the object described above, yet another aspect of the present invention provides a plasma etching processing apparatus employed to etch a silicon layer of a workpiece with a processing gas containing a mixed gas constituted of HBr gas, O₂ gas and SiF₄ gas and further mixed with both of or either of SF₆ gas and NF₃ gas by using a pre-patterned mask within an airtight processing container, characterized in that first high-frequency power with a first frequency and second high-frequency power with a second frequency lower than the first frequency are applied to a lower electrode on which the workpiece is placed.

It is desirable to set the first frequency to 27.12 MHz or higher and the second frequency to 3.2 MHz in this plasma etching processing apparatus. In addition, it is desirable to form a horizontal magnetic field perpendicular to the electric field, achieving an intensity level of 170 gauss or higher over a central area of the workpiece, within the airtight processing container. It is desirable to set the temperature of the lower electrode equal to or higher than 70° C. and equal to or lower than 250° C. and to set the pressure inside the processing container equal to or higher than 150 mTorr and equal to or lower than 500 mTorr.

In order to achieve the object described above, yet another aspect of the present invention provides a plasma etching processing apparatus employed to etch a silicon layer of a workpiece with a processing gas containing a mixed gas constituted of HBr gas, O₂ gas and SiF₄ gas and further mixed with both of or either of SF₆ gas and NF₃ gas by using a pre-patterned mask within an airtight processing container, characterized in that high frequency power with a frequency of 13.56 MHz is applied to a lower electrode on which the workpiece is placed, that a horizontal magnetic field perpendicular to an electric field and achieving an intensity level of 170 gauss or higher over a central area of the workpiece is formed inside the airtight processing container and that the temperature of the lower electrode is set equal to or higher than 70° C. and equal to or lower than 250° C. and the pressure inside the processing container is set equal to or higher than 150 mTorr and equal to or lower than 500 mTorr.

By adopting either of the structures described above, holes achieving a high aspect ratio with a small hole diameter or groove width of 1 μm or less can be formed in a desired shape at the silicon layer.

It is to be noted that the explanation in the specification is provided by assuming that 1 mTorr=10⁻3×101325/760) Pa and that 1 sccm=(10⁻⁶ /60) m³/sec.

### BRIEF DESCRIPTION OF THE DRAWINGS

FIG. 1 is a schematic sectional view of the structure adopted in the plasma etching apparatus achieved in a first embodiment of the present invention;

FIG. 2 is a schematic sectional view of a workpiece before the etching process is executed in the first embodiment;

FIG. 3 is a schematic sectional view of the workpiece having undergone the etching process executed in the first embodiment;

FIG. 4A presents diagrams showing the pressure dependency of the individual parameters observed in the first embodiment;

FIG. 4B presents diagrams showing the pressure dependency of the individual parameters observed in the first embodiment;

FIG. 4C presents diagrams showing the pressure dependency of the individual parameters observed in the first embodiment;

FIG. 5A presents diagrams showing the lower electrode temperature dependency of the individual parameters observed in the first embodiment;

FIG. 5B presents diagrams showing the lower electrode temperature dependency of the individual parameters observed in the first embodiment;

FIG. 5C presents diagrams showing the lower electrode temperature dependency of the individual parameters observed in the first embodiment;

FIG. 6A presents diagrams showing the effects on the individual parameters achieved by adding SiF₄ gas in the first embodiment;

FIG. 6B presents diagrams showing the effects on the individual parameters achieved by adding SiF₄ gas in the first embodiment;

FIG. 6C presents diagrams showing the effects on the individual parameters achieved by adding SiF₄ gas in the first embodiment;

FIG. 7A presents diagrams showing the SiF₄ gas flow rate dependency of the etching rate at the silicon oxide film layer observed in the first embodiment;

FIG. 7B presents diagrams showing the SiF₄ gas flow rate dependency of the etching rate at the silicon oxide film layer observed in the first embodiment;

FIG. 8A presents diagrams showing the pressure dependency of the individual parameters observed in a second embodiment;

FIG. 8B presents diagrams showing the pressure dependency of the individual parameters observed in a second embodiment;

FIG. 8C presents diagrams showing the pressure dependency of the individual parameters observed in a second embodiment;

FIG. 9A presents diagrams showing the lower electrode temperature dependency of the individual parameters observed in the second embodiment;

FIG. 9B presents diagrams showing the lower electrode temperature dependency of the individual parameters observed in the second embodiment;

FIG. 9C presents diagrams showing the lower electrode temperature dependency of the individual parameters observed in the second embodiment;

FIG. 10A presents diagrams showing the effects on the individual parameters achieved by adding SiF₄ gas in the second embodiment; and

FIG. 10B presents diagrams showing the effects on the individual parameters achieved by adding SiF₄ gas in the second embodiment; and

FIG. 10C presents diagrams showing the effects on the individual parameters achieved by adding SiF₄ gas in the second embodiment; and

FIG. 11A presents diagrams showing the SiF₄ gas flow rate dependency of the etching rate at the silicon oxide film layer observed in the second embodiment.

FIG. 11B presents diagrams showing the SiF₄ gas flow rate dependency of the etching rate at the silicon oxide film layer observed in the second embodiment.

### DETAILED DESCRIPTION OF THE PREFERRED EMBODIMENTS

The following is a detailed explanation of the preferred embodiments of the etching method and the plasma etching processing apparatus according to the present invention, given in reference to the attached drawings. It is to be noted that the same reference numerals are assigned to components having substantially identical functions and structural features in the description and the drawings to preclude the necessity for a repeated explanation thereof.

(First Embodiment)

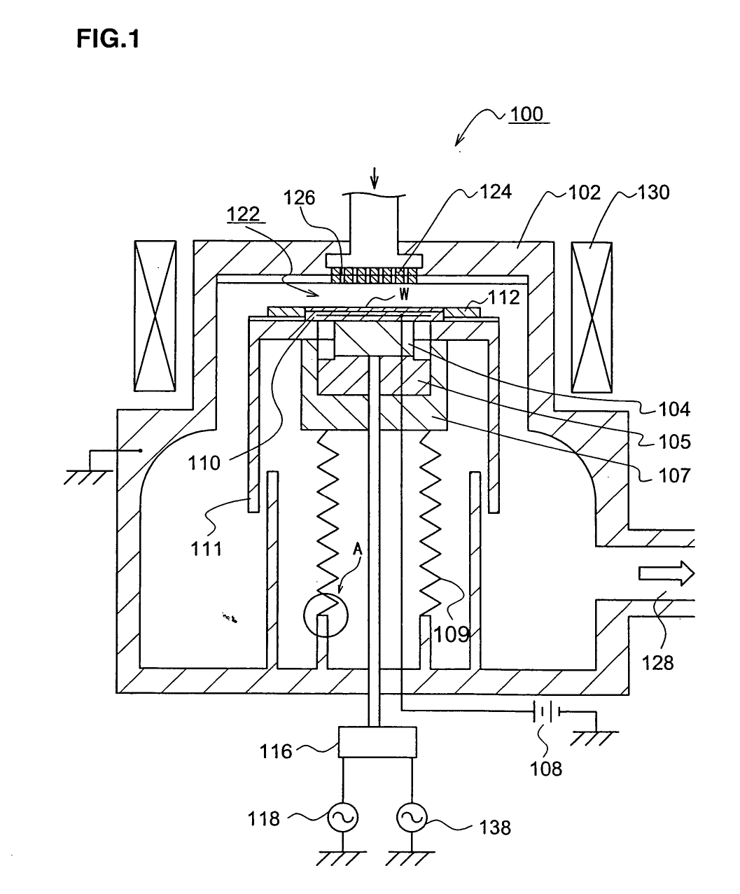

FIG. 1 is a schematic sectional view of the structure of a plasma etching apparatus 100 achieved in an embodiment of the present invention. A processing container 102 of the plasma etching apparatus 100 in FIG. 1 is constituted of aluminum having an aluminum oxide film formed at the surface thereof through, for instance, anodizing and is grounded.

A lower electrode 104 to be used as a stage on which a workpiece such as a semiconductor wafer W is placed and also to function as a susceptor is disposed within the processing container 102. The lower electrode 104 is allowed to move up/down freely by an elevator shaft (not shown).

Over the lower area of the side surface of the lower electrode 104, a quartz member 105 to function as an insulating member and a conductive member 107 which is placed in contact with a bellows 109 are formed. The bellows 109, which may be constituted of, for instance, stainless steel, is in contact with the processing container 102. Thus, the conductive member 107 is grounded via the bellows 109 and the processing container 102. In addition, a bellows cover 111 is disposed so as to enclose the quartz member 105, the conductive member 107 and the bellows 109.

An electrostatic chuck 110 connected to a high voltage DC source 108 is provided at the stage surface of the lower electrode 104. A focus ring 112 is disposed of so as to encircle the electrostatic chuck 110.

Two high-frequency source systems, i.e., a first high-frequency source 118 and a second high-frequency source 138, are connected to the lower electrode 104 via a matcher 116. The frequency of the power from the first high-frequency source 118 (to be referred to as a first frequency) is set higher than the frequency of the power from the second high-frequency source 138 (to be referred to as a second frequency). By applying high-frequency power from two separate systems and controlling the power from the two systems independently of each other, a bowing phenomenon whereby the side walls of holes being formed become etched in a curve can be prevented and, as a result, the shape of the holes can be controlled more accurately.

It is desirable to set the first frequency to, for instance, 27.12 MHz or higher. It is particularly desirable to ensure that the first frequency as at least 27.12 MHz if there is no magnetic field in the processing space. However, the offers first frequency may be set as low as 13.56 MHz as explained later if a magnetic field is created in the processing space with a magnet 130 or the like since the plasma density can be raised with the magnetic field to achieve a higher etching rate for the silicon. The second frequency may be set to, for instance, 3.2 MHz.

An upper electrode 124 which is grounded via the processing container 102 is disposed at the ceiling of the processing container 102. The upper electrode 124 having numerous gas outlets holes 126 through which a processing gas is supplied is connected with a gas supply source (not shown) from which the processing gas is supplied into the processing space 122.

Outside the processing container 102, a magnet 130 which generates a horizontal magnetic field in the processing space 122 is disposed. The magnet 130 generates a magnetic field achieving an intensity level of 170 gauss over a central area of the workpiece, for instance, in the processing space 122. If the magnetic field formed by the magnet 130 achieves an intensity level of 170 gauss or higher as in this example, a single high-frequency source capable of outputting power with a frequency of, for instance, 13.56 MHz, may be used.

An evacuating port 128 connecting with an evacuation system (not shown) such as a vacuum pump is formed at the processing container 102 at a lower position, so as to maintain a predetermined degree of vacuum inside the processing container 102.

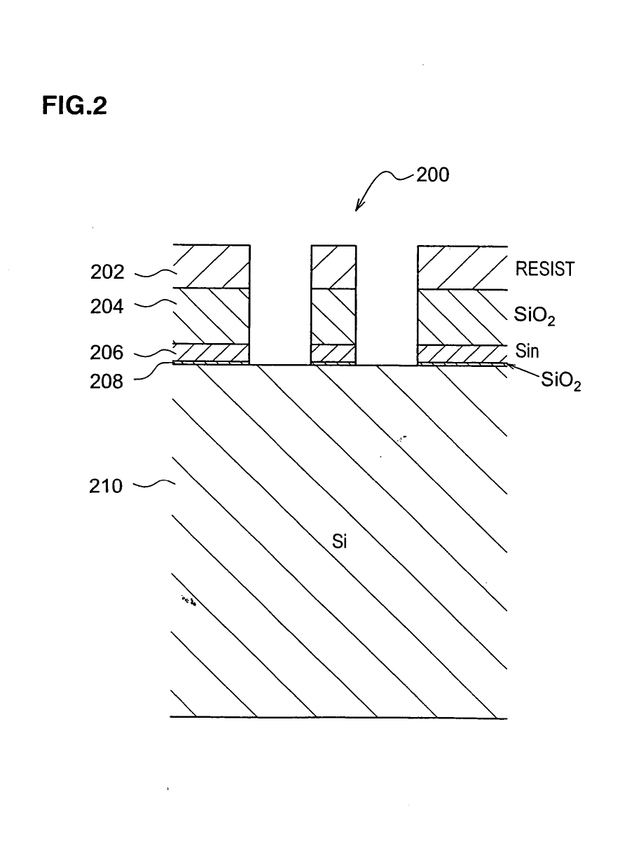

Next, the operation of the plasma etching apparatus 100 described above is explained in reference to FIGS. 1 and 2. FIG. 2 is a schematic sectional view showing the structure of a workpiece 200 to undergo the etching process.

As shown in FIG. 2, the workpiece 200, which may be a semiconductor wafer W with a diameter of 200 mm, includes a resist layer 202 having a pattern of holes having a diameter of 200 nm formed at the surface thereof through a photolithography process. Under the resist layer 202, a silicon oxide film layer (SiO₂ film) 204, which may be, for instance, a CVD oxide film, is formed over a thickness of approximately 700 to 2200 nm. Under the silicon oxide film layer 204, a silicon nitride film layer (SiN film) 206 is formed over a thickness of approximately 200 nm. Under the silicon nitride film layer 206, a silicon thermal oxide film layer (SiO₂ film) 208 to constitute a gate insulating film is formed over a thickness of several nm or less.

A specific pattern is formed in advance at the silicon oxide film layer 204, the silicon nitride film layer 206 and the silicon thermal oxide film layer 208 through etching by using the resist layer 202 as a mask at the workpiece 200 adopting the structure described above. Subsequently, the resist layer 202 is removed. Through this process, the silicon oxide film layer 204 and the silicon nitride film layer 206 become a mask to be used to etch a silicon (Si) layer 210.

The workpiece having a mask constituted of the silicon oxide film layer 204 and the silicon nitride film layer 206 having undergone the specific patterning process as described above is then transferred into the processing container 102 through a workpiece transfer port (not shown) and is placed onto the lower electrode 104. The processing container 102 is evacuated in this state through the evacuating port 128 by using the vacuum pump (not shown), and then the processing gas is supplied into the processing container 102 it via the gas outlet holes 126 from the gas supply source (not shown).

The processing gas containing HBr gas, O₂ gas and SiF₄ gas is further mixed with SF₆ gas or NF₃ gas. The flow rates of the individual gases constituting the processing gas may be set to, for instance, 100 to 600 sccm for the HBr gas, 2 to 60 sccm for the O₂ gas, 2 to 50 sccm for the SiF₄ gas and 1 to 60 sccm for the SF₆ gas or 2 to 80 sccm for the NF₃ gas. The flow rate settings for the gas is constituting the processing gas are to be described in detail later together with details of the temperatures at the stage surface of the lower electrode 104, the upper electrode 124 and the inner wall surface of the processing container 102.

With the gas flow rates set at the specific values and the temperatures at the various areas set to predetermined levels, the pressure inside the processing container 102 is set to a predetermined value (e.g., 200 mTorr, to be detailed later). In addition, the first high-frequency power with the first frequency from the first high-frequency source 118 and the second high-frequency power with the second frequency from the second high-frequency source 138 are applied to the lower electrode 104 via the matcher 116.

Since the first frequency should be 27.12 MHz or higher as explained earlier, it is set to 40.68 MHz in this embodiment. The second frequency is set to 3.2 MHz. The level of the power from the first high-frequency source 118 may be, for instance, 600 to 1500 W, and the level of the power from the high-frequency source 138 may be, for instance, 500 to 1200 W.

By supplying high-frequency power with frequencies different from each other from the two power supply systems as described above, the disassociation of the SiF₄ gas is promoted to achieve more efficient etching. The workpiece becomes etched through the operation described above.

Next, in reference to FIGS. 2 through 6 and 7, an explanation is given on the etching conditions selected in the first embodiment. It is to be noted that the etching conditions selected in the first embodiment are etching conditions under which holes with a diameter of 0.18 μm are formed in a desirable manner.

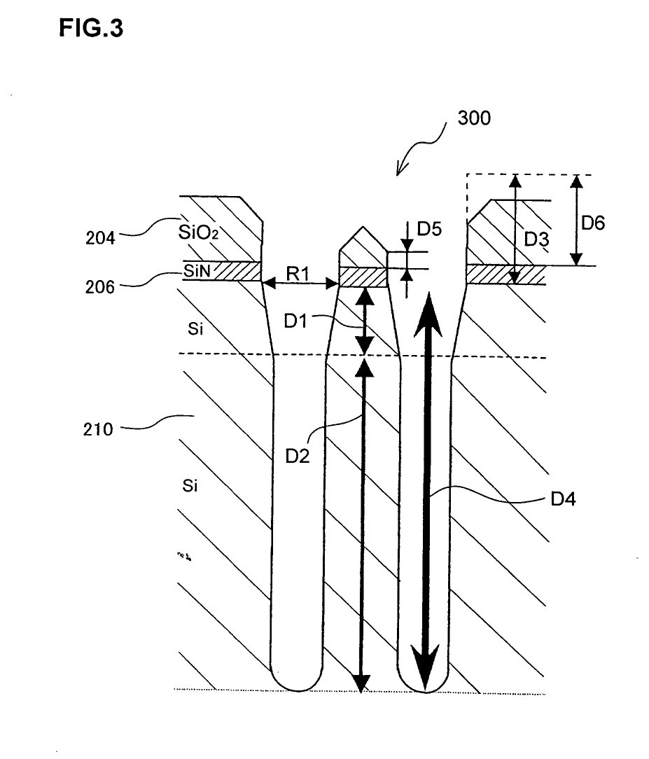

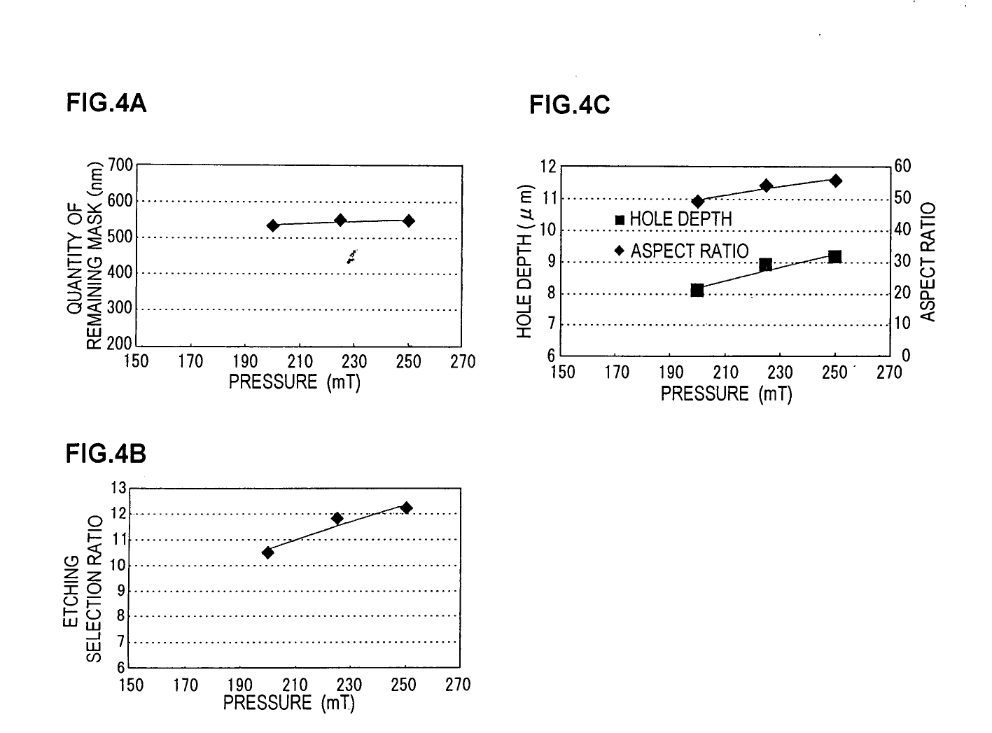

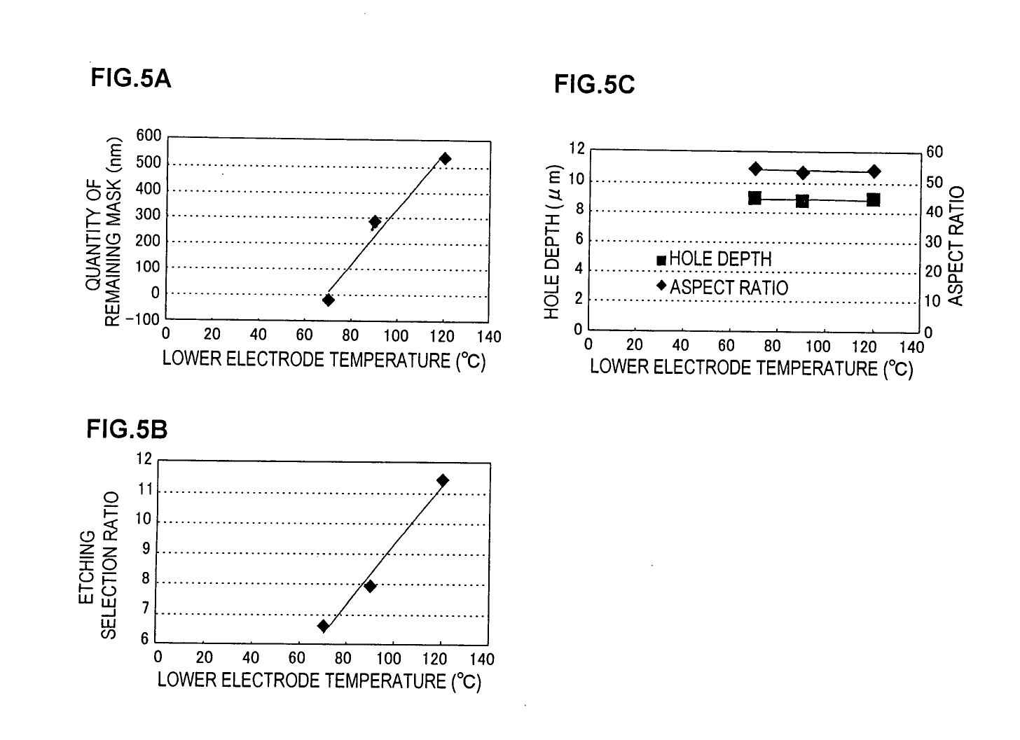

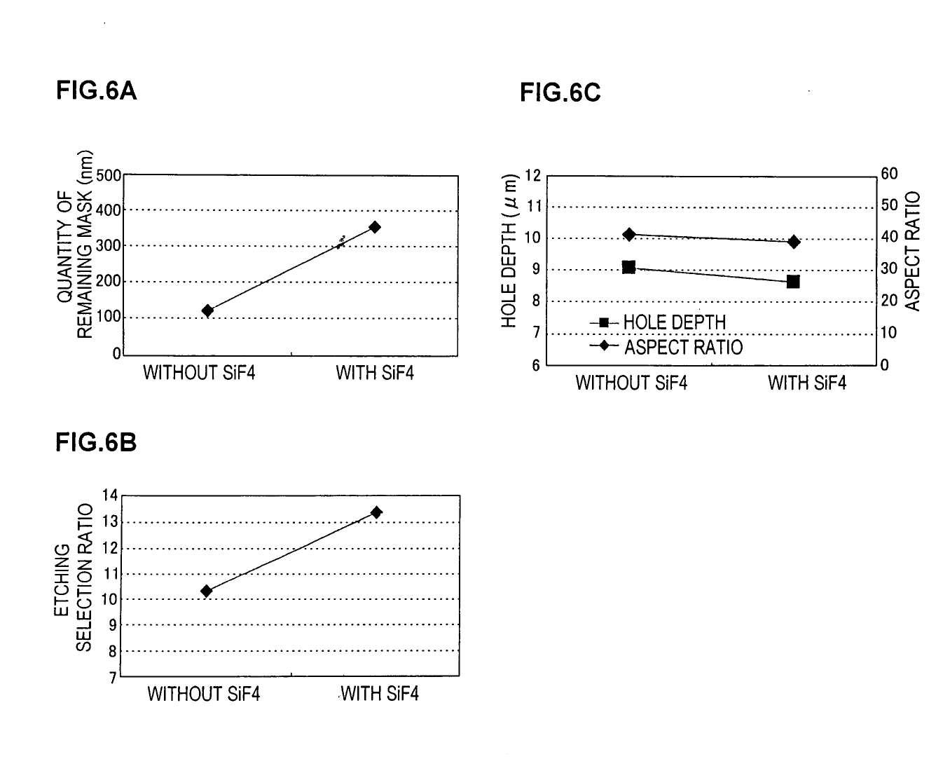

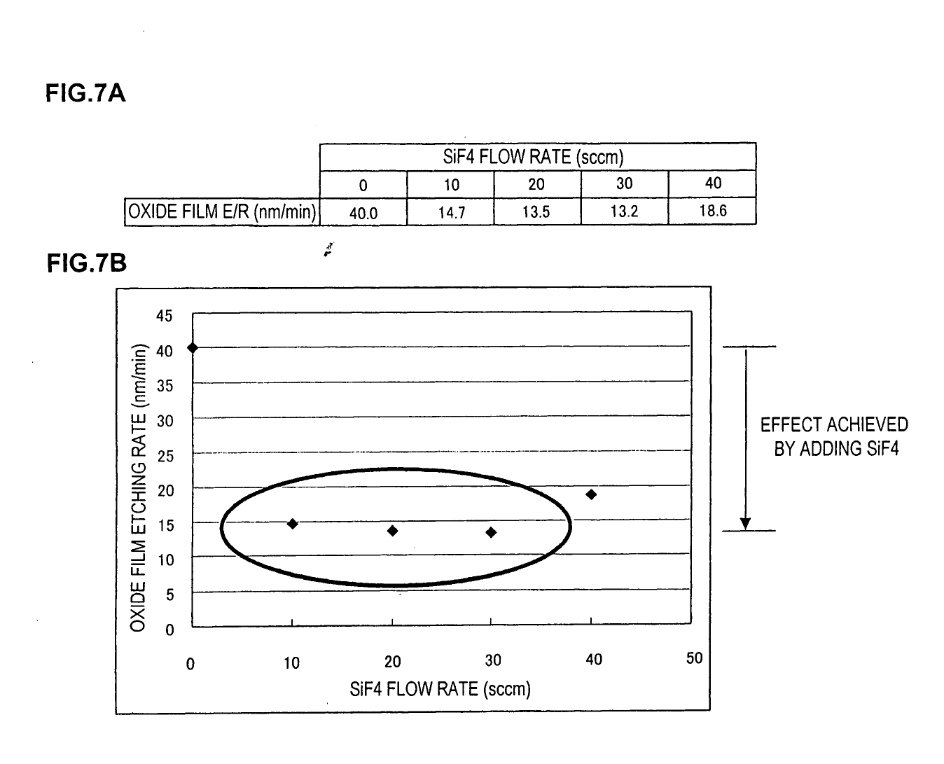

FIG. 3 is a schematic sectional view of a workpiece 300 having undergone the etching process (the silicon thermal oxide film layer 208 is not shown) and FIG. 4 presents diagrams showing the pressure dependency of the various parameters. FIG. 5 presents diagrams showing the lower electrode temperature dependency of the individual parameters and FIG. 6 presents diagrams showing the effects on the individual parameters achieved by adding the SiF₄ gas. FIG. 7 shows the SiF₄ gas flow rate dependency of the etching rate at the silicon oxide film layer.

As shown in FIG. 3, the workpiece 300 is etched to form holes with a hole diameter R1 by using the mask constituted of the silicon oxide film layer 204 and the silicon nitride film layer 206 (may be collectively referred to as a mask material hereafter). The initial thicknesses of the mask material and the silicon oxide film layer 204 are respectively D3 and D6.

The etching process is implemented by executing a plurality of steps in the embodiment. An initial step is a so-called breakthrough (also referred to as “B.T.”) step in which the silicon oxide film layer formed through, for instance, natural oxidation at the surface of the silicon layer 210 (see FIG. 2) to undergo the etching process is removed.

Next, a first step (corresponds to “1-1, 1-2” in the table) is executed to etch the silicon layer over a depth D 1 so as to achieve a hole shape with a wide top and a narrower bottom, eg., a funnel shape. The depth D1 may be, for instance, 1.5 μm. In the embodiment, the first step includes two sub-steps so as to form holes in the desired shape through rigorous control by adjusting the etching conditions.

Next, a second step (corresponds to “2-1, 2-2, . . . 2-6” in the table) is executed to etch the remaining silicon layer 210 over a depth D2. In the embodiment, the second step includes six sub-steps so as to form holes in the desired shape through rigorous control by adjusting the etching conditions.

Through the steps described above, holes each having a hole diameter R1 and a hole depth D4 are formed at the workpiece 300. The silicon oxide film layer 204 with the initial depth D6 achieves a depth D5 (also referred to as the quantity of remaining silicon film oxide mask) at the shoulder of each hole entrance after these steps. The etching selection ratio at the shoulder is expressed as D4/(D6−D).

Next, the dependency of various parameters such as the remaining silicon oxide film mask quantity D5, the etching selection ratio, the hole depth D4 and the aspect ratio (D4/R1) on the pressure inside the processing container 102 is examined in reference to FIG. 4 presenting the results of etching tests conducted by varying the pressure inside the processing chamber. FIG. 4A shows the pressure dependency of the remaining silicon oxide film mask quantity D5 on the pressure inside the processing container 102 and FIG. 4B shows the pressure dependency of the etching selection ratio on the pressure inside the processing container 102. FIG. 4C shows the pressure dependency of the hole depth D4 and the aspect ratio (D4/R1) on the pressure inside the processing container 102.

The etching tests were conducted under first etching conditions indicated in Table 1-1. In Table 1-1, the etching conditions selected for the individual steps are indicated. It is to be noted that under the first etching conditions, the upper electrode temperature, the processing container inner wall temperature and the lower electrode temperature were set to 80° C., 60° C. and 120° C. respectively. In addition, the symbol (*) indicates that the etching process was executed by gradually changing the pressure inside the processing container from 200 mTorr to 250 mTorr. During the tests, the etching process was executed by adjusting the pressure inside the processing container from 200 mTorr to 225 mTorr and then to 250 mTorr.

TABLE 1-1

| | | | | | | | | | SUBSTRATE BACK | | |
|---|---|---|---|---|---|---|---|---|---|---|---|
| | PRESSURE | | | | | | | | SURFACE | | |
| | SETTING | | | PROCESSING GAS FLOW | | | | | PRESSURE | | |
| | DURING | | | RATES | | | | | (Torr) | | ETCHING |
| | STEP | POWER (W) | | (sccm) | | | | | CENTRAL | PERIPHERAL | PERIOD |
| STEP | (mTorr) | 40.68 MHz | 3.2 MHz | HBr | NF₃ | SF₆ | SiF₄ | O₂ | AREA | AREA | (sec) |
| B.T | 50 | 400 | 100 | 150 | 2.5 | | | 1 | 13 | 35 | 10 |
| 1-1 | 125 | 700 | 300 | 220 | 32 | | | 22 | 13 | 25 | 35 |
| 1-2 | 125 | 700 | 400 | 220 | 32 | | | 22 | 13 | 25 | 35 |
| 2-1 | 200 | 800 | 700 | 300 | | 3 | 1 | 18 | 10 | 10 | 20 |
| 2-2 | * | 600 | 500 | 240 | | 9.2 | 4 | 19 | 7.5 | 18 | 70 |
| 2-3 | * | 600 | 550 | 240 | | 9.2 | 8 | 20 | 5 | 15 | 180 |
| 2-4 | * | 600 | 600 | 240 | | 9.2 | 16 | 22.7 | 5 | 17 | 660 |
| 2-5 | * | 600 | 700 | 240 | | 9.2 | 16 | 22.7 | 5 | 17 | 180 |
| 2-6 | 225 | 600 | 800 | 240 | | 9.2 | 16 | 23.2 | 5 | 17 | 120 |

Since the etching rate of silicon becomes lower as the hole becomes deeper, the output from the high-frequency source 138 was increased in the second step compared to the first step so as to prevent the etching rate from becoming lowered by raising the energy level of the ions in the plasma under the etching conditions indicated above. The output was gradually increased particularly in the later sub-steps 2-2 to 2-6. In addition, the flow rate of the O₂ gas was set higher in the later sub-steps to sustain the desired etching selectivity by prompting a deposit of a protective film on top of the mask material. It is to be noted that the output from the high-frequency source 138 and the flow rate of the O₂ gas should be increased concurrently during the second step.

As the processing container internal pressure was varied from 200 mTorr to 250 mTorr as indicated by the symbol (*) under these etching conditions, the etching selection ratio, the hole depth D4 and the aspect ratio all increased in correspondence to the pressure increase, as indicated in FIGS. 4B and 4C. An etching selection ratio of at least 6 and an aspect ratio of at least 30 could be achieved.

The quantity of the remaining silicon oxide film mask D5, however, remained unchanged even as the processing container internal pressure was adjusted. Thus, we can conclude that better etching results are achieved by setting the pressure inside the processing container at a higher level under these etching conditions. However, if the pressure is set too high, the reaction products will not be evacuated readily and will become deposited on the workpiece, which slows down the etching process to result in a lowered etching rate of the silicon. By taking these factors into consideration, it is desirable to maintain the pressure level inside the processing container within a range of 150 mTorr to 500 mTorr in practical application, and it is even more desirable to sustain the pressure level within a range of 150 mTorr to 350 mTorr.

Next, the dependency of the various parameters on the temperature of the lower electrode 104 is examined in reference to FIG. 5 presenting the results of etching tests conducted by varying the temperature of the lower electrode 104. FIG. 5A shows the temperature dependency of the quantity of the remaining silicon oxide film mask D5 on the temperature of the lower electrode 104 and FIG. 5B shows the temperature dependency of the etching selection ratio on the temperature of the lower electrode 104. FIG. 5c shows the temperature dependency of the hole depth D4 and the aspect ratio (D4/R1) on the temperature of the lower electrode 104.

The etching tests were conducted under second etching conditions indicated in Table 1-2. Table 1-2 indicates etching conditions selected for each step. It is to be noted that under the second etching conditions, the base temperature levels of the upper electrode, the processing container inner wall and the lower electrode were 80° C., 60° C. and 120° C. respectively, and the etching process was executed by varying the lower electrode temperature within a range of 70° to 120° C. In the example, the lower electrode temperature was varied from 70° C. to 90° C. and then to 120° C.

TABLE 1-2

| | | | | | | | | | SUBSTRATE BACK | | |
|---|---|---|---|---|---|---|---|---|---|---|---|
| | PRESSURE | | | | | | | | SURFACE | | |
| | SETTING | | | PROCESSING GAS FLOW | | | | | PRESSURE | | |
| | DURING | | | RATES | | | | | (Torr) | | ETCHING |
| | STEP | POWER (W) | | (sccm) | | | | | CENTRAL | PERIPHERAL | PERIOD |
| STEP | (mTorr) | 40.68 MHz | 3.2 MHz | HBr | NF₃ | SF₆ | SiF₄ | O₂ | AREA | AREA | (sec) |
| B.T | 50 | 400 | 100 | 150 | 2.5 | 0 | 0 | 1.0 | 13 | 35 | 10 |
| 1-1 | 125 | 700 | 300 | 220 | 32 | 0 | 0 | 23.3 | 13 | 35 | 37 |
| 1-2 | 125 | 700 | 400 | 220 | 32 | 0 | 0 | 23.3 | 13 | 35 | 40 |
| 2-1 | 200 | 800 | 700 | 300 | 0 | 3.0 | 1.0 | 16 | 10 | 10 | 20 |
| 2-2 | 200 | 800 | 700 | 300 | 0 | 11.4 | 5.0 | 25.5 | 10 | 13 | 70 |
| 2-3 | 200 | 800 | 700 | 300 | 0 | 11.4 | 10.0 | 27.0 | 10 | 10 | 180 |
| 2-4 | 200 | 800 | 700 | 300 | 0 | 11.4 | 10.0 | 28.9 | 10 | 10 | 810 |

Under the second etching conditions indicated in Table 1-2, the lower electrode temperature was set to 120° C. It is to be noted that when the lower electrode temperature was set to the other levels (70° C. and 90° C.), the flow rate of the O₂ gas was adjusted so as to ensure that a constant hole depth D4 and a constant aspect ratio would be achieved. As FIGS. 5A to 5C indicate, the quantity of remaining silicon oxide film mask D5 and the etching selection ratio both increased as the lower electrode temperature rose. It is more desirable to have a significant quantity of silicon oxide film mask D5 remaining unetched in the workpiece. More specifically, it is desirable to have, for instance, 200 nm or more of the silicon oxide film mask D5 remaining unetched.

In order to ensure that a significant quantity of the silicon oxide mask D5 remains unetched and that the etching selection ratio of at least 6 is achieved, the temperature of the lower electrode should not be lower than approximately 70° C. (see FIG. 5B). In addition, since the etching uniformity within the semiconductor wafer surface become poor if the lower electrode temperature becomes too high, the lower electrode temperature should not exceed approximately 250° C. In order to ensure approximately ±5% or ±10% at worst in etching uniformity within the semiconductor wafer surface, the lower electrode temperature should not exceed approximately 150° C. It is to be noted that 200 nm or more silicon oxide film mask D5 can be left unetched by forming the initial silicon oxide film layer with a sufficient thickness in correspondence to the quantity of silicon oxide film layer expected to be etched off.

Next, the effect on the individual parameters achieved by adding the SiF₄ gas are examined based upon the results of etching tests conducted with and without the SiF₄ gas mixed into the processing gas and without having any SiF₄ gas to the processing gas presented in FIG. 6. FIG. 6A shows the effect achieved on the remaining silicon oxide film mask D5 achieved by adding the SiF₄ gas, and FIG. 6b shows the effect on the etching selection ratio achieved by adding the SiF₄ gas. FIG. 6b shows the effects on hole depth D4 and the aspect ratio (D4/R1) achieved by adding the SiF₄ gas.

The etching tests were conducted under third etching conditions indicated in Table 1-3. In Table 1-3, the etching conditions selected for the individual steps are indicated. It is to be noted that under the third etching conditions, the upper electrode temperature, the processing container inner wall temperature and the lower electrode temperature were set to 80° C., 60° C. and 70° C. respectively.

TABLE 1-3

| | | | | | | | | | SUBSTRATE BACK | | |
|---|---|---|---|---|---|---|---|---|---|---|---|
| | PRESSURE | | | | | | | | SURFACE | | |
| | SETTING | | | PROCESSING GAS FLOW | | | | | PRESSURE | | |
| | DURING | | | RATES | | | | | (Torr) | | ETCHING |
| | STEP | POWER (W) | | (sccm) | | | | | CENTRAL | PERIPHERAL | PERIOD |
| STEP | (mTorr) | 40.68 MHz | 3.2 MHz | HBr | NF₃ | SF₆ | SiF₄ | O₂ | AREA | AREA | (sec) |
| B.T | 150 | 400 | 350 | 150 | 2.5 | 0 | 0 | 1 | 4 | 40 | 10 |
| 1-1 | 90 | 850 | 500 | 240 | 29 | 0 | 20 | 20 | 4 | 40 | 70 |
| 2-1 | 200 | 800 | 500 | 300 | 21 | 0 | 0/20 | 14 | 10 | 20 | 240 |
| 2-2 | 200 | 800 | 800 | 300 | 21 | 0 | 0/20 | 15 | 10 | 20 | 480 |

0/20 in the SiF₄ gas field in Table 1-3 indicates that the flow rate of the SiF₄ gas was set to 0 sccm when no SiF₄ gas was added into the processing gas during the second step and that the flow rate was set to 20 sccm when the SiF₄ gas was added into the processing gas during the second step. FIGS. 6A to 6C indicate that when the SiF₄ gas was added into the processing gas, the quantity of the remaining silicon oxide film mask D5 and the etching selection ratio increased while the hole depth D4 and the aspect ratio remained substantially unchanged when the SiF₄ gas was added under the third etching conditions.

The relationship between the etching rate of the oxide film and the quantity of SiF₄ gas added into the processing gas observed during an etching process executed by gradually changing the quantity of the SiF₄ gas is presented in FIG. 7. FIG. 7A presents specific etching rate values (nm/min) obtained by changing the quantity of the SiF₄ gas within a range of 0 to 30 sccm, whereas FIG. 7B presents a graph obtained by plotting the etching rate values (nm/min).

FIG. 7 indicates that the etching rate of the silicon oxide film layer 204 constituting the mask material was greatly lowered when a small quantity of SiF₄ gas was added into the processing gas. It is desirable to add the SiF₄ gas in a quantity within a range of approximately 2 to 50 sccm. FIG. 7 also indicates that by adding approximately 10 to 30 sccm of SiF₄ gas, the etching rate can be lowered to half or less the initial etching rate. As a result, the etching selection ratio can be at least doubled. This allows us to conclude that better etching results can be achieved by mixing approximately 10 to 30 sccm of a fluoro gas, i.e., the SiF₄ gas.

Processing similar to that described above can be executed in a plasma etching apparatus in which high-frequency power with a frequency of 13.56 MHz is applied to the lower electrode 104 on which the workpiece is placed, a horizontal magnetic field perpendicular to an electric field achieving an intensity level of 170 gauss or higher over a central area of the workpiece is formed within the processing container, the temperature of the lower electrode 104 is set within a range of 70° C. to 150° C. and the pressure inside the processing container is set equal to or higher than 150 mTorr and equal to or lower than 350 mTorr.

Next, an etching process executed on the silicon layer of a workpiece by using a mixed gas containing NF₃ gas instead of SF₆ gas is examined. Etching tests were conducted under fourth etching conditions indicated in Table 1-4. It is to be noted that under the fourth etching conditions, the upper electrode temperature, the processing container inner wall temperature and the lower electrode temperature were set to −80° C., 60° C. and 75° C. respectively. The distance between the upper electrode and lower electrode was set to 27 mm.

TABLE 1-4

| | | | | | | | | | SUBSTRATE BACK | | |
|---|---|---|---|---|---|---|---|---|---|---|---|
| | PRESSURE | | | | | | | | SURFACE | | |
| | SETTING | | | PROCESSING GAS FLOW | | | | | PRESSURE | | |
| | DURING | | | RATES | | | | | (Torr) | | ETCHING |
| | STEP | POWER (W) | | (sccm) | | | | | CENTRAL | PERIPHERAL | PERIOD |
| STEP | (mTorr) | 40.68 MHz | 3.2 MHz | HBr | NF₃ | SF₆ | SiF₄ | O₂ | AREA | AREA | (sec) |
| 1-1 | 150 | 850 | 400 | 240 | 29 | 0 | 20 | 14 | 4 | 40 | 70 |
| 2-2 | 250 | 1200 | 800 | 300 | 45 | 0 | 20 | 18 | 10 | 20 | 540 |

An etching rate of 755 nm/min, a hole depth of 8.21 μm and an aspect ratio of 56.2 were achieved by etching the silicon (Si) layer under a hole patterned mask with a diameter of 135 nm under those conditions. These etching results indicated that holes achieving a high aspect ratio can be formed without their side walls becoming curved through an etching process executed by using a mixed gas containing NF₃ gas instead of SF₆ gas.

As described above, by adopting the etching method and the etching processing apparatus achieved in the first embodiment, holes with a hole diameter of approximately 0.2 μm, a hole depth of 8 μm or more and a high aspect ratio of at least 30 can be formed in a desirable shape at the silicon layer through etching. In addition, by selecting appropriate etching conditions within the preferred ranges explained above, such holes can be formed in an even more desirable shape at an even better etching rate.

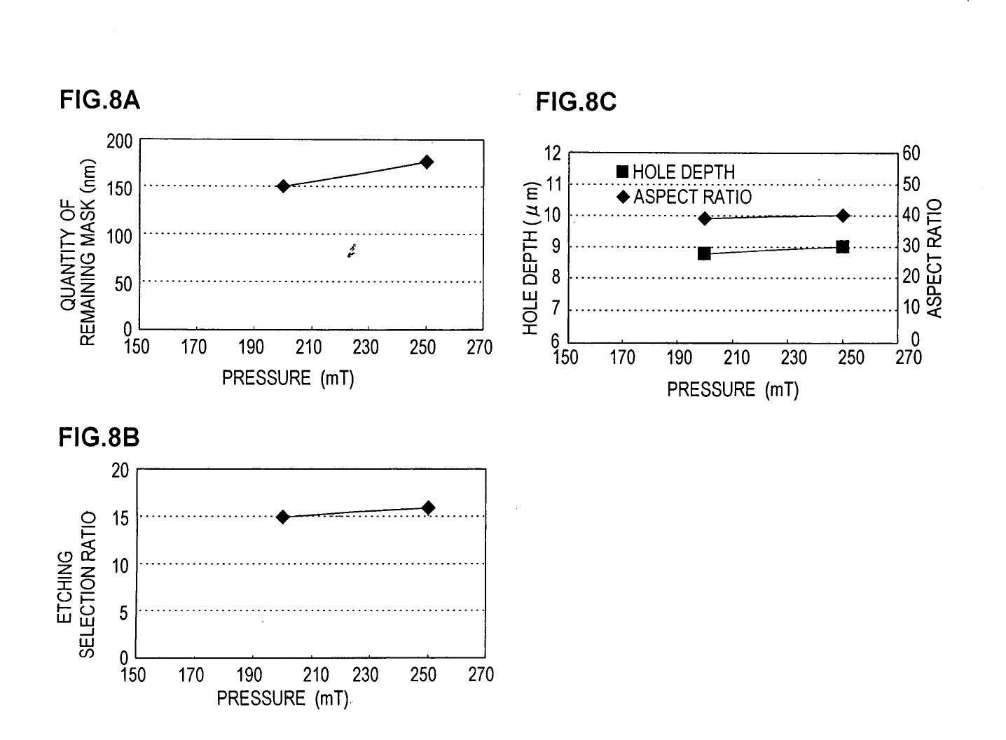

Next, the etching method adopted in the plasma processing apparatus 100 in the second embodiment of the present invention is explained in reference to FIGS. 8 to 11. In the etching process executed in the second embodiment, the first frequency of the power applied to the lower electrode 104 is set to 27.12 MHz. It is to be noted that holes formed through the etching process executed in the second embodiment are similar to those shown in FIGS. 2 and 3. An explanation is given here on the formation of holes with a hole diameter of 0.18 μm, similar to the holes formed in the first embodiment

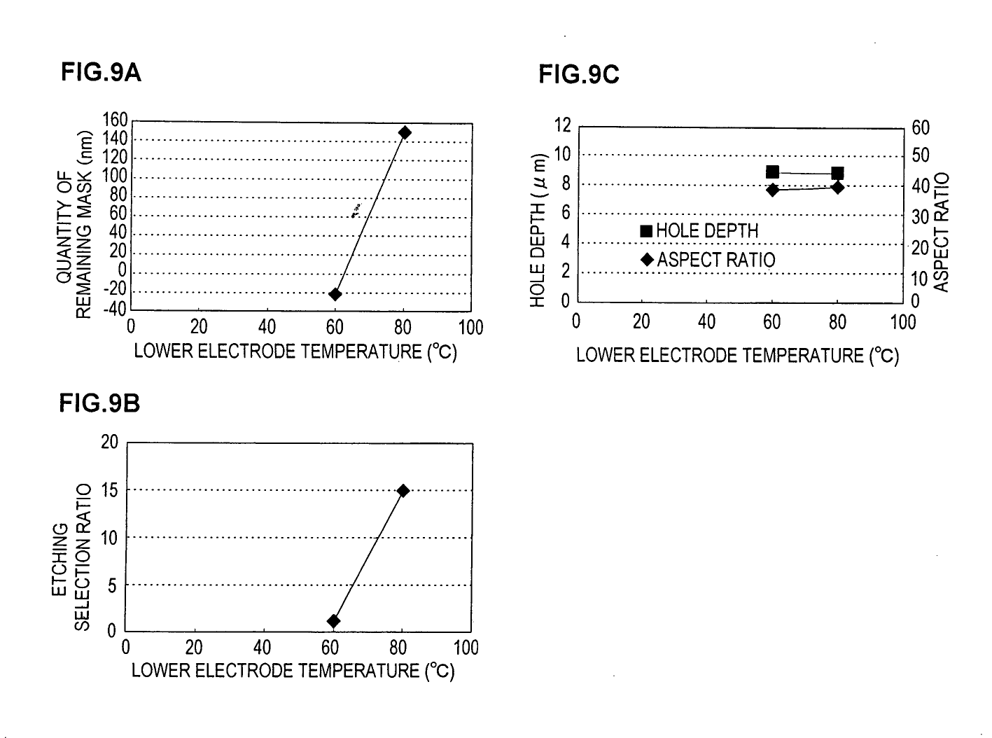

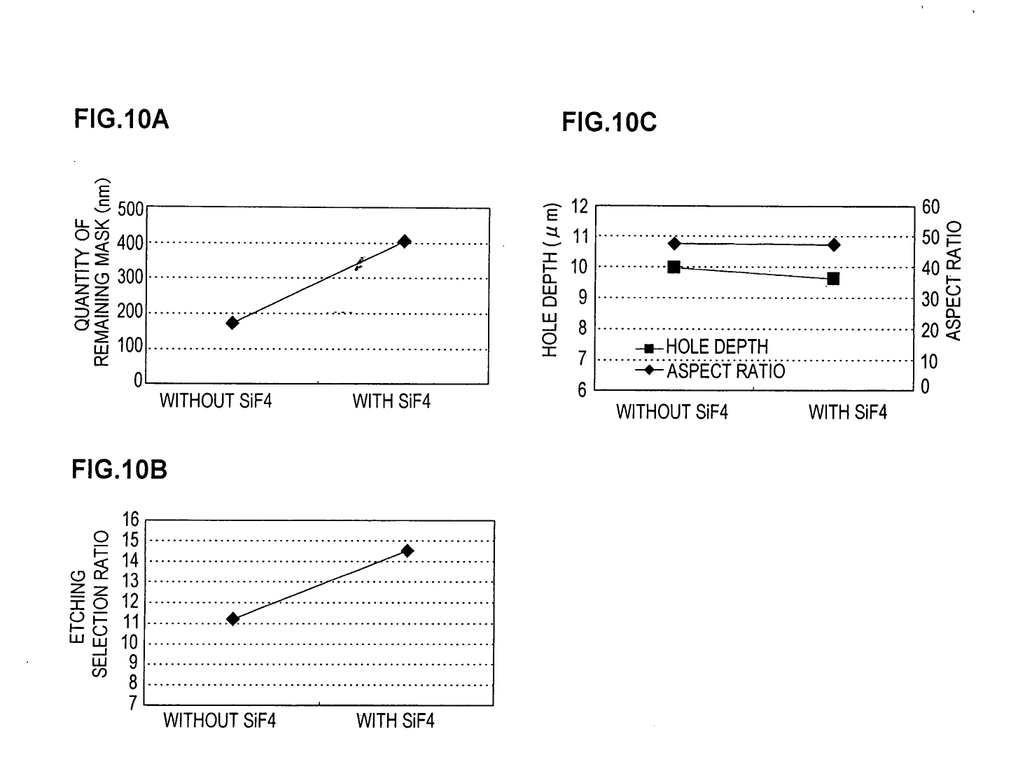

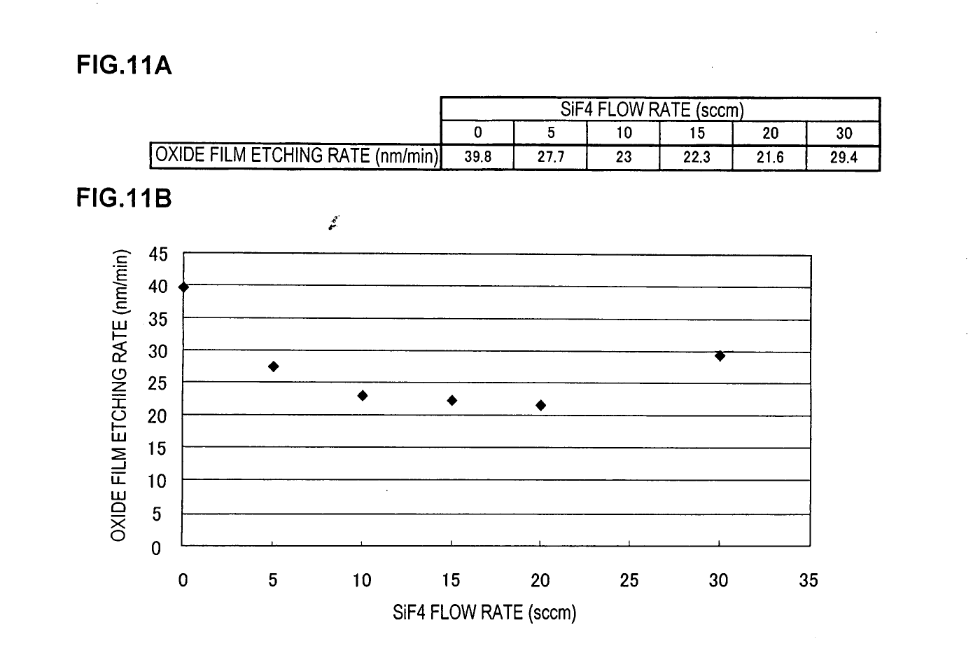

FIGS. 8 to 11 present the results of tests conducted by executing the etching process in the second embodiment. FIGS. 8 to 11 respectively correspond to FIGS. 4 to 7 in reference to which the first embodiment has been explained. More specifically, FIG. 8 presents diagrams showing the pressure dependency of the various parameters on the pressure inside the processing container, and FIG. 9 presents diagrams showing the lower electrode temperature dependency of the parameters. FIG. 10 presents diagrams showing the effects on the individual parameters achieved by having SiF₄ gas into the processing gas and FIG. 11 shows the SiF₄ gas flow rate dependency of the etching rate at the silicon oxide film layer. It is to be noted that since similar steps to those in the first embodiment are executed in the etching process in the second embodiment, they are not explained in detail. However, neither the first step nor the second step includes any sub-steps in the second embodiment.

First, the dependency of the various parameters on the pressure inside the processing container 102 is examined in reference to FIG. 8 presenting the results of etching tests conducted by varying the pressure inside the processing chamber. FIG. 8A shows the pressure dependency of the remaining silicon oxide film mask quantity D5 on the pressure inside the processing container 102 and FIG. 8B shows the pressure dependency of the etching selection ratio on the pressure inside the processing container 102. FIG. 8C shows the pressure dependency of the hole depth D4 and the aspect ratio (D4/R1) on the pressure inside the processing container 102.

The etching tests were conducted under fifth etching conditions indicated in Table 2-1. In Table 2-1, the etching conditions selected for the individual steps are indicated. It is to be noted that under the fifth etching conditions, the upper electrode temperature, the processing container inner wall temperature and the lower electrode temperature were set to 80° C., 80° C. and 80° C. respectively. In addition, the symbol (*) indicates that the etching process was executed by gradually changing the pressure inside the processing container from 200 mTorr to 250 mTorr. During the tests, the etching process was executed by adjusting the pressure inside the processing container from 200 mTorr to 250 mTorr.

TABLE 2-1

| | | | | | | | | | SUBSTRATE BACK | | |
|---|---|---|---|---|---|---|---|---|---|---|---|
| | PRESSURE | | | | | | | | SURFACE | | |
| | SETTING | | | PROCESSING GAS FLOW | | | | | PRESSURE | | |
| | DURING | | | RATES | | | | | (Torr) | | ETCHING |
| | STEP | POWER (W) | | (sccm) | | | | | CENTRAL | PERIPHERAL | PERIOD |
| STEP | (mTorr) | 27.12 MHz | 3.2 MHz | HBr | NF₃ | SF₆ | SiF₄ | O₂ | AREA | AREA | (sec) |
| B.T | 150 | 400 | 350 | 150 | 2.5 | 0 | 0 | 1.0 | 10 | 20 | 10 |
| 1-1 | 150 | 1000 | 350 | 300 | 36.0 | 0 | 0 | 20.0 | 4 | 20 | 80 |
| 2-1 | * | 800 | 800 | 150 | 14.0 | 0 | 10.0 | 9.0 | 4 | 20 | 600 |

Since the etching rate of silicon becomes lower as the hole becomes deeper, the output from the high-frequency source 138 was increased in the second step compared to the first step so as to prevent the etching rate from becoming lowered by raising the energy level of the ions in the plasma under the fifth etching conditions indicated above.

As the processing container internal pressure was varied from 200 mTorr to 250 mTorr as indicated by the symbol (*) under the fifth etching conditions, the etching selection ratio, the hole depth D4 and the aspect ratio all increased in correspondence to the pressure increase, as indicated in FIGS. 8B and 8C. An etching selection ratio of at least 6 and an aspect ratio of at least 30 could be achieved, and it was even possible to achieve an etching selection ratio of 15 or higher and an aspect ratio of approximately 40 or higher.

The quantity of the remaining silicon oxide film mask D5, however, remained almost unchanged even as the processing container internal pressure was adjusted. Thus, we can conclude that better etching results are achieved by setting the pressure inside the processing container at a higher level under these etching conditions. However, if the pressure is set too high, the reaction products will not be evacuated readily and become deposited on the workpiece, which slows down the etching process to result in a lowered etching rate of the silicon. By taking these factors into consideration, it is desirable to maintain the pressure level inside the processing container within a range of 150 mTorr to 500 mTorr in practical application, and it is even more desirable to sustain the pressure level within a range of 150 mTorr to 350 mTorr, as in the first embodiment.

Next, the dependency of the various parameters on the temperature of the lower electrode 104 is examined in reference to FIG. 9 presenting the results of etching tests conducted by varying the temperature of the lower electrode 104. FIG. 9A shows the temperature dependency of the remaining silicon oxide film mask quantity D5 on the temperature of the lower electrode 104 and FIG. 9B shows the temperature dependency of the etching selection ratio on the temperature of the lower electrode 104. FIG. 9C shows the temperature dependency of the hole depth D4 and the aspect ratio (D4/R1) on the temperature of the lower electrode 104.

The etching tests were conducted under sixth etching conditions shown in Table 2-2. Table 2-2 indicates etching conditions selected for each step. It is to be noted that under the sixth etching conditions, the base temperature levels of the upper electrode, the processing container inner wall and the lower electrode were 80° C., 80° C. and 80° C. respectively, and the etching process was executed by varying the lower electrode temperature within a range of 60° to 80° C. In the example, the lower electrode temperature was varied from 60° C. to 80° C.

TABLE 2-2

| | | | | | | | | | SUBSTRATE BACK | | |
|---|---|---|---|---|---|---|---|---|---|---|---|
| | PRESSURE | | | | | | | | SURFACE | | |
| | SETTING | | | PROCESSING GAS FLOW | | | | | PRESSURE | | |
| | DURING | | | RATES | | | | | (Torr) | | ETCHING |
| | STEP | POWER (W) | | (sccm) | | | | | CENTRAL | PERIPHERAL | PERIOD |
| STEP | (mTorr) | 27.12 MHz | 3.2 MHz | HBr | NF₃ | SF₆ | SiF₄ | O₂ | AREA | AREA | (sec) |
| B.T | 150 | 400 | 350 | 150 | 2.5 | 0 | 0 | 1.0 | 10 | 20 | 10 |
| 1-1 | 150 | 1000 | 350 | 300 | 36.0 | 0 | 0 | 20.0 | 4 | 20 | 80 |
| 2-1 | 200 | 800 | 700 | 150 | 14.0 | 0 | 10.0 | 9.0 | 4 | 20 | 600 |

Under the sixth etching conditions, the lower electrode temperature was set to 80° C. It is to be noted that when the lower electrode temperature was set to the other levels (60° C. and 80° C.), the flow rate of the O₂ gas was adjusted so as to ensure that a constant hole depth D4 and a constant aspect ratio would be achieved. As FIGS. 9A to 9C indicate, the remaining silicon oxide film mask quantity D5 and the etching selection ratio both increased as the lower electrode temperature rose. It is more desirable to have a significant quantity of silicon oxide film mask D5 remaining unetched at the workpiece. More specifically, it is desirable to have, for instance, 200 nm or more of the silicon oxide film mask D5 remaining unetched.

In order to ensure that a significant quantity of the silicon oxide mask D5 remains unetched and that the etching selection ratio of at least 6 is achieved, the temperature of the lower electrode should not be lower than approximately 70° C. (see FIG. 9B). In addition, since the etching uniformity within the semiconductor wafer surface becomes poor if the lower electrode temperature becomes too high, the lower electrode temperature should not exceed approximately 250° C. In order to ensure approximately ±5% or ±10% at worst in the etching uniformity within the semiconductor wafer surface, the lower electrode temperature should not exceed approximately 150° C. It is to be noted that 200 nm or more silicon oxide film mask D5 can be left unetched by forming an initial silicon oxide film layer with a sufficient thickness in correspondence to the quantity of silicon oxide film layer expected to be etched off.

Next, the effects on the individual parameters achieved by adding SiF₄ gas are examined based upon the results of etching tests conducted with and without SiF₄ gas mixed into the processing gas, presented in FIG. 10. FIG. 10A shows the effect on the remaining silicon oxide film mask quantity D5 achieved by adding the SiF₄ gas, and FIG. 10B shows the effect on the etching selection ratio achieved by adding the SiF₄ gas. FIG. 10C shows the effects on hole depth D4 and the aspect ratio (D4/R1) achieved by adding the SiF₄ gas.

The etching tests were conducted under seventh etching conditions indicated in Table 2-3. In Table 2-3, the etching conditions selected for the individual steps are indicated. It is to be noted that under the seventh etching conditions, the upper electrode temperature, the processing container inner wall temperature and the lower electrode temperature were set to 80° C., 60° C. and 60° C. respectively.

TABLE 2-3

| | | | | | | | | | SUBSTRATE BACK | | |
|---|---|---|---|---|---|---|---|---|---|---|---|
| | PRESSURE | | | | | | | | SURFACE | | |
| | SETTING | | | PROCESSING GAS FLOW | | | | | PRESSURE | | |
| | DURING | | | RATES | | | | | (Torr) | | ETCHING |
| | STEP | POWER (W) | | (sccm) | | | | | CENTRAL | PERIPHERAL | PERIOD |
| STEP | (mTorr) | 27.12 MHz | 3.2 MHz | HBr | NF₃ | SF₆ | SiF₄ | O₂ | AREA | AREA | (sec) |
| B.T | 150 | 400 | 350 | 150 | 2.5 | 0 | 0 | 1.0 | 10 | 20 | 5 |
| 1-1 | 150 | 1000 | 350 | 150 | 18.0 | 0 | 0 | 20.0 | 4 | 20 | 65 |
| 2-1 | 200 | 1000 | 700 | 300 | 21.0 | 0 | 0/5 | 9.0 | 4 | 20 | 600 |

0/5 in the SiF₄ gas field in Table 2-3 indicates that the flow rate of the SiF₄ gas was set to 0 sccm when no SiF₄ gas was added into the processing gas during the second step and that the flow rate was set to 5 sccm when the SiF₄ gas was added into the processing gases during the second step. FIGS. 10A to 10C indicate that when the SiF₄ gas was added into the processing gas, the remaining silicon oxide film mask quantity D5 and the etching selection ratio increased while the hole depth D4 and the aspect ratio remained substantially unchanged when the SiF₄ gas was added under the seventh etching conditions.

The relationship between the etching rate of the oxide film and the quantity of SiF₄ gas added into the processing gas observed during an etching process executed by gradually changing the quantity of the SiF₄ gas is presented in FIG. 11. FIG. 11a presents specific etching rate values (nm/min) obtained by changing the quantity of the SiF₄ gas within a range of 0 to 30 sccm, whereas FIG. 11B presents a graph obtained by plotting the etching rate values (nm/min).

FIG. 11 indicates that the etching rate of the silicon oxide film layer 204 constituting the mask material demonstrated a tendency similar to that indicated in FIG. 7 in that when a small quantity of SiF₄ gas was added into the processing gas, the etching rate became lower. It is desirable to add the SiF₄ gas in a quantity within a range of approximately 2 to 50 sccm and it is even more desirable to add the SiF₄ gas within a flow rate range of approximately 2 to 35 sccm. FIG. 11 also indicates that by adding approximately 10 to 30 sccm of the SiF₄ gas, the etching rate can be lowered to half or less the initial etching rate. As a result, the etching selection ratio can be at least doubled. This allows us to conclude that better etching results can be achieved by mixing approximately 10 to 30 sccm, and even more desirably, 10 to 25 sccm of a fluoro gas, i.e., the SiF₄ gas in the second embodiment as well.

As described above, by adopting the etching method and the etching processing apparatus achieved in the second embodiment, too, holes with a hole diameter of approximately 0.2 μm, a hole depth of 8 μm or more and a high aspect ratio of at least 30 can be formed in a desirable shape at the silicon layer through etching. In addition, by selecting appropriate etching conditions within the preferred ranges explained above, such holes can be formed in an even more desirable shape at an even better etching rate.

While the etching method and the etching apparatus have been particularly shown and described with respect to preferred embodiments thereof by referring to the attached drawings, the present invention is not limited to these examples and it will be understood by those skilled in the art that various changes in form and detail may be made therein without departing from the spirit, scope and teaching of the invention.

For instance, while an explanation is given above on an example in which the present invention is adopted to form holes at a silicon layer of a wafer through etching, the present invention may instead be adopted to form grooves on a wafer through etching. Advantages similar to those achieved in the hole formation can be realized when forming grooves on a wafer (e.g., at a silicon layer) by adopting the present invention. It is to be noted that when the present invention is adopted to form grooves on a wafer, their groove width corresponds to the hole diameter mentioned earlier.

In addition, while an explanation is given above on an example in which the silicon layer of the workpiece is etched by using a processing gas containing HBr gas, O₂ gas and SiF₄ gas and further mixed with SF₆ gas or an NF₃ gas, the present invention is not limited to this example and the workpiece may instead be etched by using a processing gas containing a mixed gas constituted of HBr gas, O₂ gas and SiF₄ gas and further mixed with both SF₆ gas and NF₃ gas.

The present invention described above, in which the workpiece is processed with a mixed gas constituted of HBr gas, O₂ gas and SiF₄ gas and further mixed with either SF₆ gas or NF₃ gas by using a mask having a pre-patterned silicon oxide film layer and applying high-frequency power with two different frequencies supplied from two supply systems to the lower electrode on which the workpiece is placed within an airtight processing container, provides an etching method and a plasma etching processing apparatus that enable formation of holes or grooves achieving a high aspect ratio of 30 or more with a hole diameter (or a groove width) of, for instance, 1 μm or less in a desirable shape at the silicon layer.

### INDUSTRIAL APPLICABILITY

The present invention may be adopted in an etching method and a plasma etching processing apparatus and more specifically, it may be adopted to achieve an etching method and a plasma etching processing apparatus that enable formation of holes or grooves with a high aspect ratio at a silicon layer.

1. An etching method for etching a silicon layer of a workpiece with a processing gas containing a mixed gas constituted of HBr gas, O₂ gas and SiF₄ gas and further mixed with both of or either of SF₆ gas and NF₃ gas by using a pre-patterned mask inside an airtight processing container, characterized in:
that a first high-frequency power with a first frequency and second high-frequency power with a second frequency lower than the first frequency are applied to a lower electrode on which the workpiece is placed.

2. An etching method according to claim 1, characterized in:
that the first frequency is set equal to or higher than 27.12 MHz and the second frequency is set to 3.2 MHz.

3. An etching method according to claim 1, characterized in:
that a horizontal magnetic field perpendicular to an electric field is formed inside the airtight processing container.

4. An etching method according to claim 3, characterized in:
that the horizontal magnetic field achieves an intensity level of 170 gauss or higher over a central area of the workpiece.

5. An etching method according to claim 1, characterized in:
that the temperature of the lower electrode is set equal to or higher than 70° C. and equal to or lower than 250° C.

6. An etching method according to claim 1, characterized in:
that the pressure inside the container is set equal to or higher than 150 mTorr and equal to or lower than 500 mTorr.

7. An etching method according to claim 1, characterized in:
that the flow rates of the gases constituting the processing gas are set to 100 to 600 sccm for the HBr gas, 2 to 60 sccm for the O₂ gas, 2 to 50 sccm for the SiF₄ gas and 1 to 60 sccm for the SF₆ gas if the SF₆ gas is to be contained in the processing gas and 2 to 80 sccm for the NF₃ gas if the NF₃ gas is to be contained in the processing gas.

8. An etching method according to claim 1, characterized in:
that the aspect ratio of holes or grooves formed through etching is 30 or higher.

9. An etching method according to claim 1, characterized in:
that the pre-patterned mask includes at least a silicon oxide film layer.

10. An etching method according to claim 9, characterized in:
that the ratio of a quantity of the silicon layer constituting an etching target material that becomes etched to a quantity of a shoulder of the mask the becomes etched is 6 or higher.

11. An etching method for etching a silicon layer of a workpiece with a processing gas containing a mixed gas constituted of HBr gas, O₂ gas and SiF₄ gas and further mixed with either of SF₆ gas and NF₃ gas by using a pre-patterned mask inside an airtight processing container, characterized in:
that the temperature of a lower electrode on which the workpiece is placed is set equal to or higher than 70° C. and equal to or lower than 250° C.

12. An etching method for etching a silicon layer of a workpiece with a processing gas containing a mixed gas constituted of HBr gas, O₂ gas and SiF₄ gas and further mixed with either of SF₆ gas and NF₃ gas by using a pre-patterned mask inside an airtight processing container, characterized in:
that the pressure inside the processing container is set equal to or higher than 150 mTorr and equal to or lower than 500 mTorr.

13. An etching method for etching a silicon layer of a workpiece with a processing gas containing a mixed gas constituted of HBr gas, O₂ gas and SiF₄ gas and further mixed with both of or either of SF₆ gas and NF₃ gas by using a pre-patterned mask inside an airtight processing container, and by applying first high frequency power with a first frequency and second high frequency power with a second frequency lower than the first frequency to a lower electrode on which the workpiece is placed, comprising:
a first step in which an upper portion of the silicon layer is etched in a funnel shape; and
a second step executed following the first step, in which the remaining silicon layer is etched to form a smooth surface, a section of which ranges substantially perpendicular to the surface of the workpiece.

14. An etching method according to claim 13, characterized in:
that the second high-frequency power is increased during the second step compared to in the first step.

15. An etching method according to claim 13, characterized in:
that a plurality of sub-steps are executed during the second step.

16. An etching method according to claim 15, characterized in:
that the level of the second high-frequency power and of the flow rate of the O₂ gas are varied in the individual sub-steps executed during the second step.

17. An etching method according to claim 16, characterized in:
that the flow rate of the O₂ gas is further increased in later sub-steps among the plurality of sub-steps constituting the second step.

18. A plasma etching processing apparatus employed to etch a silicon layer of a workpiece with a processing gas containing a mixed gas constituted of HBr gas, O₂ gas and SiF₄ gas and further mixed with both of or either of SF₆ gas and NF₃ gas by using a pre-patterned mask inside an airtight processing container, characterized in:
that first high-frequency power with a first frequency and second high-frequency power with a second frequency lower than the first frequency are applied to a lower electrode on which the workpiece is placed.

19. A plasma etching processing apparatus according to claim 18, characterized in:
that the first frequency is set equal to or higher than 27.12 MHz and the second frequency is set to 3.2 MHz.

20. A plasma etching processing apparatus according to claim 18, characterized in:
that a horizontal magnetic field perpendicular to an electric field is formed inside the airtight processing container.

21. A plasma etching processing apparatus according to claim 20, characterized in:
that the horizontal magnetic field achieves an intensity level of 170 gauss or higher over a central area of the workpiece.

22. A plasma etching processing apparatus according to claim 18, characterized in:
that the temperature of the lower electrode is set equal to or higher than 70° C. and equal to or lower than 250° C.

23. A plasma etching processing apparatus according to claim 18, characterized in:
that the pressure inside the container is set equal to or higher than 150 mTorr and equal to or lower than 500 mTorr.

24. A plasma etching processing apparatus employed to etch a silicon layer of a workpiece with a processing gas containing a mixed gas constituted of HBr gas, O₂ gas and SiF₄ gas and further mixed with both of or either of SF₆ gas and NF₃ gas by using a pre-patterned mask inside an airtight processing container, characterized in:
that high frequency power with a frequency of 13.56 MHz is applied to a lower electrode on which the workpiece is placed;
that a horizontal magnetic field perpendicular to an electric field and achieving an intensity level of 170 gauss or higher over a central area of the workpiece is formed inside the airtight processing container;
that the temperature of the lower electrode is set equal to or higher than 70° C. and equal to or lower than 250° C.; and
that the pressure inside the processing container is set equal to or higher than 150 mTorr and equal to or lower than 500 mTorr.
